(19) United States
(12) Patent Application Publication
(10) Pub. No.: US 2009/0166810 A1
(43) Pub. Date: Jul. 2, 2009

(54) Semiconductor Device Crack-Deflecting Structure and Method

(76) Inventors: Daniel Joseph Stillman, Garland, TX (US); Charles Anthony Odegard, McKinney, TX (US); Gregory Barton Hotchkiss, Richardson, TX (US); Richard Willson Arnold, McKinney, TX (US)

Correspondence Address: TEXAS INSTRUMENTS INCORPORATED, P O BOX 655474, M/S 3999, DALLAS, TX, 75265, US

(21) Appl. No.: 11/965,849

(22) Filed: Dec. 28, 2007

(51) Int. Cl. H01L 23/544; H01L 21/71

(52) U.S. Cl. 257/620; 438/400; 257/E23.179; 257/E21.536

(57) ABSTRACT

The invention relates to microelectronic semiconductor devices, and to mass-production of the same on semiconductor wafers with novel crack-deflecting structures and methods. According to the invention, a semiconductor device includes an active circuit area surrounded by an inactive area and circumscribed with a bulwark having a crack-deflecting face oriented toward the periphery of the device. Embodiments of the invention are disclosed, in which a semiconductor device, or multiple devices on a wafer, include bulwarks having series of minor arcs with their chords oriented toward the peripheries of the devices. Additional embodiments of the invention described include bulwarks having series of right angles oriented toward the peripheries of the devices. Examples of the invention also include preferred embodiments wherein the bulwarks further comprise series of discrete pickets, parallel bulwarks, and bulwarks in combination with scribe seals.

### TECHNICAL FIELD

The invention relates to electronic semiconductor devices and manufacturing. More particularly, the invention relates to microelectronic semiconductor device mass-production on semiconductor wafers and to structures and methods for improved devices, wafers, and improved manufacturing processes.

### BACKGROUND OF THE INVENTION

Generally speaking, microelectronic semiconductor devices are manufactured by forming layered metallic circuit components and patterns on a semiconductor wafer. Typically, numerous such devices are formed on a single wafer. The individual devices are subsequently separated from one another by a singulation process, such as cutting along sacrificial scribe streets arranged in inactive areas of the wafer for that purpose, between active devices. After singulation, the devices undergo further processing such as cleaning, testing, and packaging.

Various singulation techniques are known in the arts, all of which carry some risk of forming cracks which may propagate into singulated devices. Widely used singulation techniques include mechanical sawing. Singulation may be accomplished by sawing alone, or by partial sawing combined with controlled breaking along the saw kerfs, a process also known as scribing and breaking. Inevitably, microchipping occurs at the wafer surface and at the edges of the kerf due to the abrasion of the sides of the saw blade. Microchipping at the edges of the kerf not only makes the kerf wider than it might otherwise be, but can also lead to further problems due to the propagation of cracks during sawing, during final singulation, or after singulation. These cracks can lead to problems such as reduced density of devices on the wafer due to the need for wider scribe streets, reduced yields, or the production of devices that ultimately develop defects such as delamination or other damage due to latent cracks, as well as slower processing times, and higher costs.

In order to isolate the devices from potential physical damage, noise, and ESD (electro-static discharge) events, and to somewhat reduce the propagation of cracks, it is known to surround the active region of each device with a scribe seal structure. When the wafer is sawn along the scribe street, a seal structure remains around the edge of each individual device. The scribe seal structures known in the arts are not always successful in preventing cracks from propagating through the seal into the active area of the device. Additional examples of efforts to minimize singulation-related problems include providing wider inactive areas, at the expense of manufacturing fewer devices per wafer. Another approach is to use laser cutting, often in combination with mechanical sawing, in efforts to reduce chipping and cracking. Such approaches are encumbered with the expenses of additional equipment and additional processing time. These examples of problems encountered in wafer singulation may be particularly acute with the fabrication of relatively delicate devices, for example, those employing copper film as a conductive interconnect material, or those making use of low-k or ultra low-k dielectric materials.

Due to these and other problems, improved semiconductor devices, wafers, and methods for facilitating the avoidance of damage to devices upon singulation would be useful and desirable in the arts. The present invention is directed to overcoming, or at least reducing the effects of one or more of the problems present in the art.

### SUMMARY OF THE INVENTION

In carrying out the principles of the present invention, in accordance with preferred embodiments, the invention provides advances in the art with novel crack-deflecting structures useful for semiconductor devices and wafers, and methods related to their manufacture.

According to one aspect of the invention, in an exemplary embodiment, a semiconductor device includes an active circuit area surrounded by an inactive area with a bulwark. The metal bulwark in the inactive area circumscribes the active area and includes a crack-deflecting face oriented toward the periphery of the device.

According to another aspect of the invention, an example of a semiconductor device embodiment includes a bulwark with a crack-deflecting face having a series of minor arcs with their chords oriented toward the periphery of the device.

According to another aspect of the invention, in a preferred embodiment, a semiconductor wafer includes a numerous integrated circuits arrayed in rows bounded by inactive areas. Scribe streets are provided for saw singulation in the inactive areas. Bulwarks are provided in the inactive areas between the scribe streets and the integrated circuits, which they circumscribe. Each bulwark also includes a crack-deflecting face oriented toward the adjacent scribe street.

According to yet another aspect of the invention, a semiconductor wafer according to a preferred embodiment is endowed with bulwarks including crack-deflecting faces with series of minor arcs having their chords oriented toward the scribe streets on the wafer.

According to another aspect of the invention, semiconductor devices and wafers according to preferred embodiments may include bulwarks constructed of discrete pickets spaced along the peripheries of the devices.

According to still another aspect of the invention, semiconductor devices and wafers according to preferred embodiments may include two or more parallel bulwarks at the peripheries of the devices.

According to another aspect of the invention, semiconductor devices and wafers according to preferred embodiments may include bulwarks constructed in combination with scribe seals at the peripheries of the devices.

The invention has advantages including but not limited to one or more of the following: improved crack-resistance in semiconductor devices; improved crack-resistance in semiconductor wafers; improved singulation processes; increased yields; reduced defects; and, reduced manufacturing costs. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a top view illustrating an example of a preferred embodiment of semiconductor devices mass-produced on a wafer according to the invention;

FIG. 2 is a simplified top macro view of a portion of a semiconductor device and wafer according to a preferred embodiment of the invention as shown in and described with reference to FIG. 1;

FIG. 3 is a simplified top ultra-macro view of a portion of a semiconductor device and wafer according to a preferred embodiment of the invention as shown in and described with reference to FIGS. 1 and 2;

FIG. 4 is a simplified top view of a portion of a semiconductor device and wafer showing an example of an alternative embodiment of the invention;

FIG. 5 is a simplified top view of a portion of a semiconductor device and wafer showing an example of an alternative embodiment of the invention; and

FIG. 6 is a simplified top view of a portion of a semiconductor device and wafer showing an example of an alternative embodiment of the invention.

References in the detailed description correspond to like references in the various drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of the embodiments shown and described are simplified or amplified for illustrating the principles, features, and advantages of the invention.

### DESCRIPTION OF PREFERRED EMBODIMENTS

The invention provides semiconductor device and wafer crack-deflecting structures and methods related to their manufacture. Novel aspects of the invention provide one or more advantages useful in the arts.

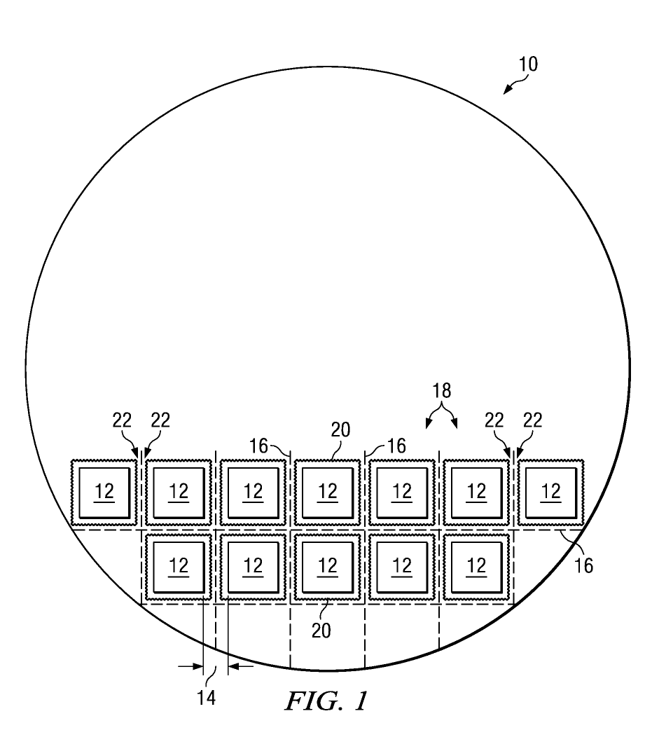

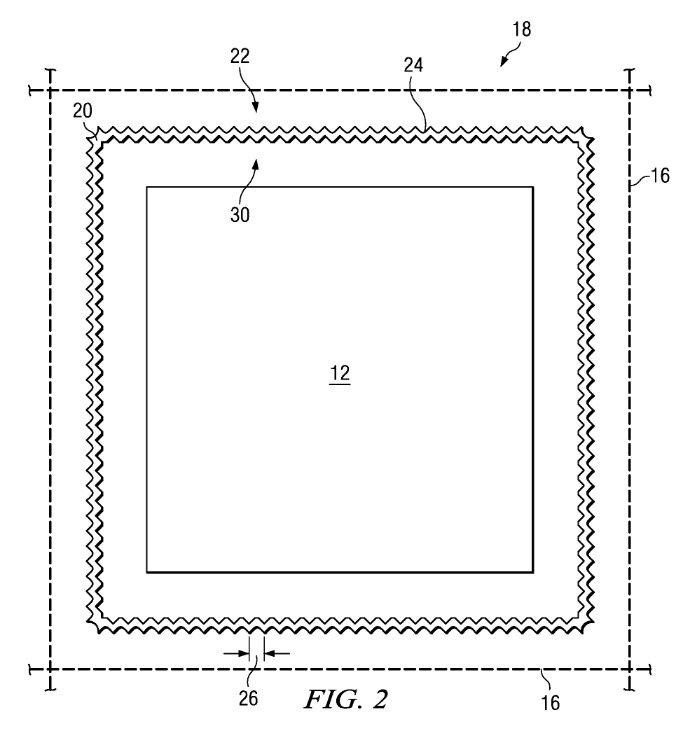

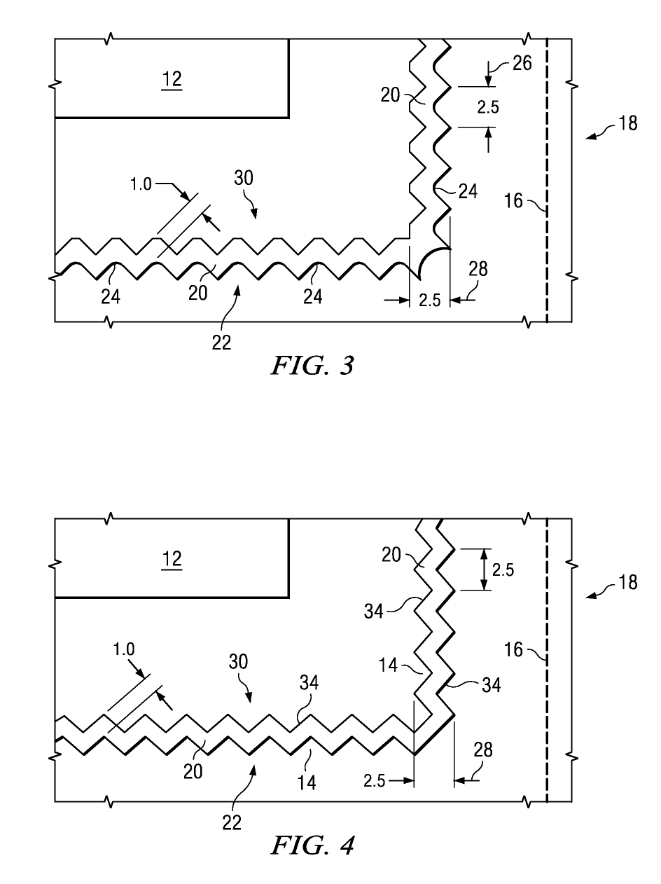

Referring primarily to FIG. 1, a preferred embodiment of the invention is shown in which a semiconductor wafer 10 includes numerous active areas, preferably integrated circuits 12, arrayed in rows and bounded by inactive areas 14. Scribe streets 16 are provided in the inactive areas 14, to facilitate singulation, such as sawing or scribing and breaking, in order to ultimately separate the individual semiconductor devices 18 from one another. Bulwarks 20 are provided in the inactive areas 14 between the scribe streets 16 and the integrated circuits 12. The bulwarks 20 are preferably made from metal used in the formation of other features on the wafer, typically primarily copper or aluminum, although other materials including non-metals may be used. The bulwarks 20 are preferably aligned running generally parallel to the scribe streets 16 and are configured to circumscribe each integrated circuit 12 to form an enclosure proximal to the periphery of each semiconductor device 18. Each bulwark 20 includes a crack-deflecting face 22, designed for deflecting cracks, which may be propagated during singulation along the scribe streets 16, from approaching the active area, or integrated circuitry 12. The crack-deflecting face 22 is oriented toward the adjacent scribe street 16, or from the corollary point of view, outboard from the active area 12 toward the periphery of the device 18. Various crack-deflecting face 22 configurations may be used without departure form the scope of the invention. It has been found through experimentation and study that a series of minor arcs 24, also shown in the more detailed FIGS. 2 and 3, are preferred or their effectiveness in halting the propagation of cracks generated during singulation along the scribe streets 16. The arcs 24 are oriented so that their chords 26 face toward the periphery of the device 18, i.e. toward the adjacent scribe street 16. Variations are possible within the scope of the invention, some examples of which are further described. It has been found in general that bulwarks having crack-deflecting faces with at least some portions oblique to the adjacent scribe street are preferable over those running parallel or perpendicular to the adjacent scribe street. Preferably, the depth of the bulwarks 20 shown and described is within the range of about 3-8 micrometers in this example, sufficiently deep to protect the active layers of the active area 12 of the device 18 from cracking, delamination, or other damage.

Now referring primarily to FIGS. 2 and 3, close-up top views of an individual semiconductor device 18, as introduced in FIG. 1, according to a preferred embodiment of the invention are shown. Dimensions shown herein are given by way of an example of a preferred embodiment of the invention demonstrating the relative configuration of a representative implementation of the invention. Practitioners of the arts will appreciate that the dimensions and proportions shown are exemplary and not exclusive or restrictive. The invention may be adapted for practice with various semiconductor device circuitry, wafer sizes, materials, aspect ratios, and densities of devices on a given wafer. The invention may be used with devices of various sizes, within a preferred range of about 2-20 millimeters on a side, for example. For the sake of the present example, a semiconductor device 18 approximately 5×5 millimeters square is shown. A representative preferred bulwark 20 is shown in FIG. 3 having a thickness of about one micrometer. As shown, the span 28 of the bulwark 20 in this example is about 2.5 micrometers, the term “span” being used herein to denominate the distance from the outside of the crack-deflecting face 22 of the bulwark 20 to the inside edge adjacent to the active area 12. Also illustrated in FIG. 3, the chord 26 of the arc 24 of the crack-deflecting face 22 of the bulwark 20 in this example is approximately 2.5 micrometers in length. Through experimentation and study in the course of developing the invention, it has been determined that a series of arcs, e.g. 24, on the crack-deflecting face 22 of the bulwark 20 is effective in achieving the objectives of the invention. Of course, the inner face 30 of the bulwark 20 may be arc-shaped as well, or straight, or angled, depending upon such factors as available area and manufacturing convenience.

Alternative embodiments of the invention may vary in their particulars and cannot all be shown and described herein. In another example of a preferred embodiment of the invention, FIG. 4 illustrates a device 18 with a bulwark 20 having a crack-deflecting face 22 made up of alternating straight segments 34 connected at obtuse angles. It is believed based upon experimentation, analysis, and study, that the bulwark 20 segments 34 angled relative to the scribe streets 16, and ultimately to the edges of the completed device 18, are advantageously more effective at deflecting cracks away from the active area 12 than scribe seals or other structures running parallel to the scribe streets. As in the previous exemplary embodiments, the bulwark 20 is designed to intercept and deflect any cracks which may be propagated along the scribe streets 16 in order to prevent the cracks from reaching the active area 12 of the device 18.

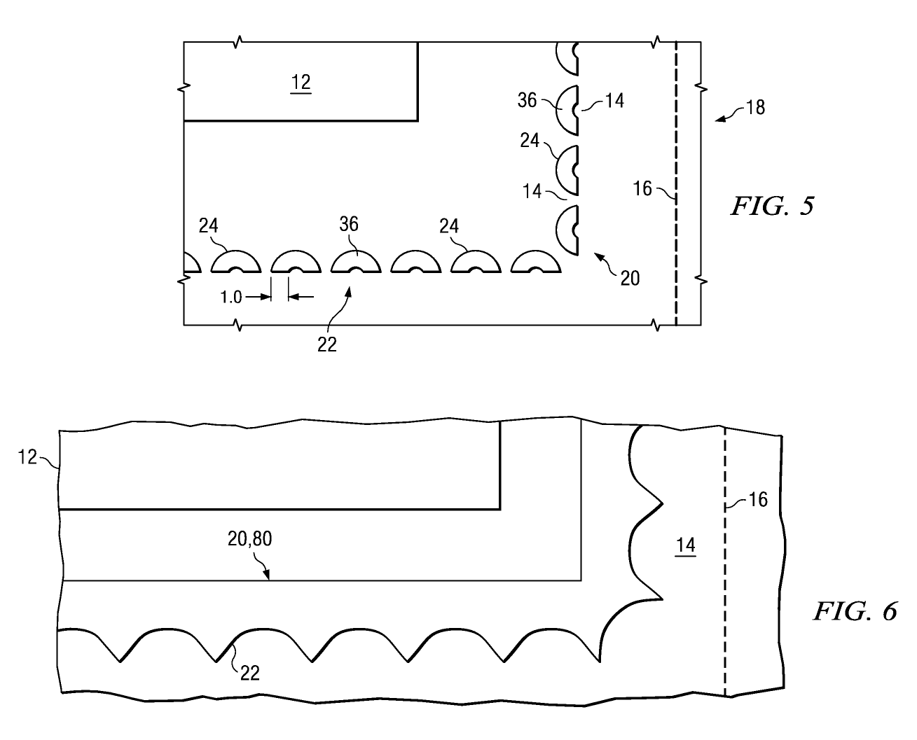

In another example of a preferred embodiment of the invention, FIG. 5 portrays a device 18 with a bulwark 20 having a crack-deflecting face 22 made up of unconnected separate arc segments, or pickets 36, closely spaced, preferably within the range of about 0.5 to 2.0 micrometers apart. It is believed that the closely spaced arc-shaped pickets 36 function to deflect cracks away from the active area 12 in a manner similar to the exemplary embodiment of FIG. 2. It should also be appreciated that the bulwark, e.g., shown at reference numeral 20 of each of the figures, may alternatively be implemented using a series of discrete pickets in many applications without departure from the invention.

A Further example of a preferred embodiment of the invention is shown in FIG. 6. A bulwark 20 is provided in an integrated combination with a scribe seal 80. The addition of the bulwark 20 with a crack-deflecting face 22 provided at the outer periphery of the device 18 advantageously reduces the susceptibility of the device 18 from damage as in other embodiments, and also reduces area requirements by eliminating inactive area between the scribe seal 80 and bulwark 20.

The methods and systems of the invention provide one or more advantages including but not limited to increased resistance to crack propagation, increased resistance to delamination, and improved singulation processes. While the invention has been described with reference to certain illustrative embodiments, those described herein are not intended to be construed in a limiting sense. Variations or combinations of steps or materials in the embodiments shown and described may be used in particular cases without departure from the invention. For example, it should be understood that parallel rows of bulwarks, as exemplified by but not limited to the preferred embodiments of bulwarks disclosed herein, may be used in various combinations with picketed and/or continuous bulwarks without departure from the invention. Combinations including bulwarks with crack-deflecting faces and integral scribe seals are also within the scope of the invention. Various modifications and combinations of the illustrative embodiments as well as other advantages and embodiments of the invention will be apparent to persons skilled in the arts upon reference to the drawings, description, and claims.

We claim:

1. A semiconductor device comprising:
an active circuit area surrounded by an inactive area; and
a bulwark situated in the inactive area and adjacent to the active circuit area, the bulwark circumscribing the active circuit area and having a crack-deflecting face oriented toward the periphery of the device.

2. The semiconductor device according to claim 1 wherein the crack-deflecting face of the bulwark further comprises a series of minor arcs having their chords oriented toward the periphery of the device.

3. The semiconductor device according to claim 1 further comprising a scribe seal combined with the bulwark.

4. The semiconductor device according to claim 1 further comprising one or more additional bulwarks circumscribed by the bulwark of claim 1.

5. The semiconductor device according to claim 1 wherein the bulwark comprises metal.

6. The semiconductor device according to claim 1 wherein the crack-deflecting face of the bulwark further comprises a series of obtuse angles oriented toward the periphery of the device.

7. The semiconductor device according to claim 1 wherein the bulwark further comprises a series of discrete pickets.

8. A semiconductor wafer comprising:
a plurality of integrated circuits arrayed in rows bounded by inactive areas;
a plurality of scribe streets for saw singulation situated in the inactive areas;
a plurality of bulwarks situated in the inactive areas between the scribe streets and the integrated circuits and circumscribing the integrated circuits; wherein
each bulwark further comprises a crack-deflecting face oriented toward the adjacent scribe street.

9. The semiconductor wafer according to claim 8 wherein the crack-deflecting faces of the bulwarks further comprise series of minor arcs having their chords oriented toward the scribe streets.

10. The semiconductor wafer according to claim 8 wherein the bulwarks further comprise series of discrete pickets.

11. The semiconductor wafer according to claim 8 wherein the bulwarks further comprise metal.

12. The semiconductor wafer according to claim 8 further comprising one or more additional bulwarks circumscribed by the bulwarks of claim 8.

13. The semiconductor wafer according to claim 8 further comprising a plurality of scribe seals combined with the bulwarks.

14. A method for manufacturing semiconductor devices comprising the steps of:
forming an array of integrated circuits on a semiconductor wafer arranged in rows and bounded by inactive areas;
providing a plurality of scribe streets in the inactive areas for saw singulation of the integrated circuits;
providing bulwarks situated in the inactive areas between the scribe streets and the integrated circuits and circumscribing the integrated circuits, each bulwark having a crack-deflecting face oriented toward the adjacent scribe street.

15. The method according to claim 14 further comprising the step of forming the crack-deflecting faces of the bulwarks in a series of minor arcs having their chords oriented toward the periphery of the integrated circuits.

16. The method according to claim 14 further comprising the step of forming the bulwarks from metal.

17. The method according to claim 14 further comprising the step of forming the bulwarks from a series of discrete pickets.

18. The method according to claim 14 further comprising the step of forming two or more parallel bulwarks circumscribing the integrated circuitry of a device.

19. The method according to claim 14 further comprising the step of forming the bulwarks integral with scribe seals.
